(19) United States
(12) Patent Application Publication
(10) Pub. No.: US 2009/0267678 A1
(43) Pub. Date: Oct. 29, 2009

(54) Integrated Circuit with Improved Data Rate

(75) Inventors: Christoph Bilger, Munich (DE); Peter Gregorius, Munich (DE); Michael Bruennert, Munich (DE); Maurizio Skerlj, Munich (DE); Wolfgang Walthes, Munich (DE); Johannes Stecker, Munich (DE); Hermann Ruckerbauer, Moos (DE); Dirk Scheideler, Munich (DE); Roland Barth, Munich (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 12/109,550

(22) Filed: Apr. 25, 2008

(51) Int. Cl. H03K 17/16

(52) U.S. Cl. 327/382

(57) ABSTRACT

An integrated circuit includes: a terminal for outputting data, a driver for providing the data to the terminal, and a switch for selectively connecting/disconnecting the driver to the terminal. The disconnection of the driver reduces the capacitive load on the connection between the terminal and driver, thus reducing limitations on data rate from factors such as data reflections that reduce signal quality. Selective connection/disconnection allows the driver to be reconnected to the terminal only when needed.

### BACKGROUND

Integrated circuits for storing data are ubiquitous. These integrated circuits, or memory devices, are typically designed to maximize the rate at which data can be written to and read from the memory.

However, the data rate that can be achieved, such as on a single wire, is limited by, among other factors, the reflections caused by capacitive loading at the beginning and the end of the wire. Such limitations currently factor into the design of the integrated circuit, and operate to reduce its data rate.

### SUMMARY

Described herein is an integrated circuit, a system comprising: a memory controller and a memory device, and a method of operating the integrated circuit. The integrated circuit comprises: a terminal for outputting data, a driver for providing the data to the terminal, and a switch for selectively connecting/disconnecting the driver to the terminal. The disconnection of the driver reduces the capacitive load on the connection between the terminal and driver, thus reducing limitations on data rate from factors such as data reflections that reduce signal quality. Selective connection/disconnection allows the driver to be reconnected to the terminal only when needed.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The invention is explained in more detail below with reference to accompanying drawings, where:

FIG. 1 shows an integrated circuit according to an embodiment;

FIG. 2 shows a further embodiment of an integrated circuit according to a further embodiment;

FIG. 3 shows a further embodiment of an integrated circuit according to a further embodiment;

FIG. 4 shows a further embodiment of an integrated circuit according to a further embodiment;

FIG. 5 shows a further embodiment of an integrated circuit according to a further embodiment;

FIG. 6 shows a further embodiment of an integrated circuit according to a further embodiment;

FIG. 7 shows a system according to a further embodiment;

FIG. 8 shows a further embodiment of a system according to a further embodiment;

FIG. 9 shows a further embodiment of a system according to a further embodiment;

FIG. 10 shows a further embodiment of a system according to a further embodiment;

FIG. 11 shows a further embodiment of a system according to a further embodiment; and

FIG. 12 shows a flow-chart of a method according to a further embodiment.

### DETAILED DESCRIPTION

In the following, embodiments of the invention are described. It should be noted that all embodiments described in the following may be combined in any way, i.e., there is no limitation that certain described embodiments may not be combined with others. Further, it should be noted that same reference signs throughout the figures denote same or similar elements.

The principles explained in the following may be applied within, among other types of integrated circuits, dynamic random access memory (DRAM), static RAM (S-RAM), floating body RAM (FB-RAM), thyristor RAM (T-RAM), ferroelectric RAM (Fe-RAM), magnetoresistive RAM (MRAM), and phase-change RAM (PC-RAM) architectures, or within systems operating such memories.

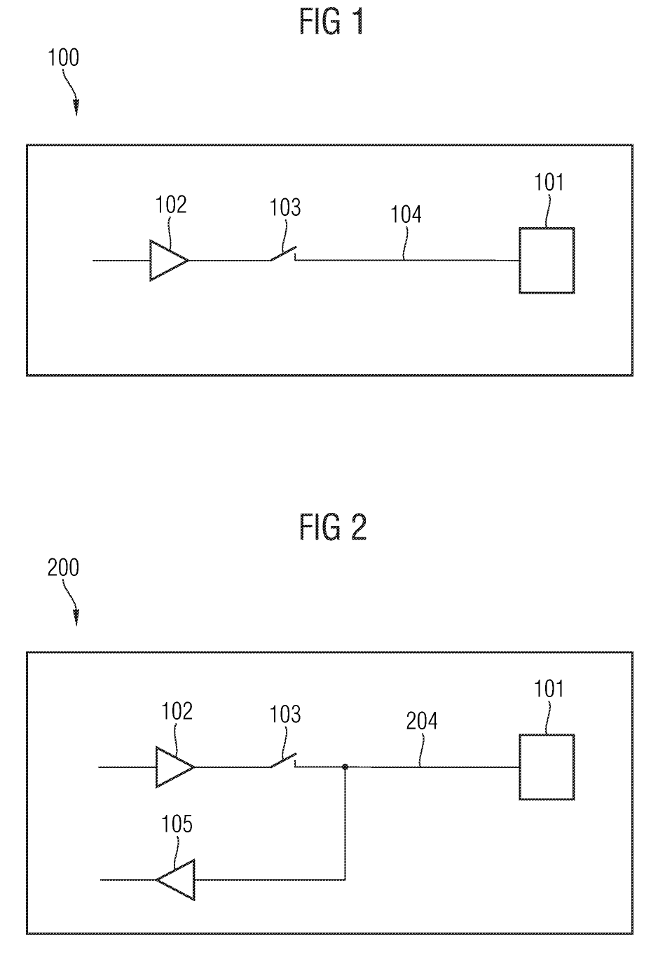

In FIG. 1, an integrated circuit 100 comprises a terminal 101, a driver 102, a switch 103, and a signal line 104. Terminal 101 may be a connection pin, a connection pad, a jack, a plug socket, a data connection circuit or the like. Driver 102 may be adapted to drive data and may also be referred to as “data transmitter” transmitting/driving data to, for example, an external controller connected to terminal 101 (not shown in FIG. 1, see below). Switch 103 may connect driver 102 to terminal 101 or to disconnect driver 102 from terminal 101. Signal line 104 is provided for connecting driver 102 to terminal 101, wherein switch 103 is provided on the signal line 104.

If driver 102 is connected to terminal 101 via signal line 104, data may be driven by driver 102 towards terminal 101. Terminal 101 may then provide the data to further elements or devices (e.g., an external controller). If switch 103 disconnects driver 102 from terminal 101, no data may be provided/driven by driver 102 to terminal 101 via signal line 104, even if driver 102 was active to drive data, i.e., in a “write mode” of the integrated circuit in which data may be written to external devices such as the external controller.

Integrated circuit 100 may be a memory device, such as a DRAM, an S-RAM, a FB-RAM, a T-RAM, a Fe-RAM, MRAM or a PC-RAM, or any other electrical, magnetic, electromagnetic, or electromechanical memory device. As stated above, driver 102 may be adapted to provide data to a controller of the memory device via terminal 101. The data driven by driver 102 may be referred to as “write data” since it is data to be written into the controller of the memory device. If seen from the side of the controller, the same data may also be referred to as “read data”; since from the side of the controller, the data is read from the memory device into the controller.

Switch 103 may be adapted to connect driver 102 to terminal 101 only if data is provided by driver 102. Thus, in a further embodiment, only if data shall be provided by driver 102 to terminal 101, switch 103 connects the driver 102 to terminal 101. If no data shall be provided by driver 102 to terminal 101, switch 103 may disconnect driver 102 from terminal 101.

When connecting driver 102 to terminal 101, a capacitance of driver 102 is in series with terminal 101 and any other connected component and may have an impact on data interchange and signal transfer, respectively. By disconnecting driver 102 from terminal 101, the capacitance of driver 102 may not have an influence on signals of signal line 104. Also, signals at terminal 101 and at any components connected thereto may not be influenced. Such influence on a signal may result from reflections on components like terminal 101 or driver 102, or any other device connected to signal line 104. The influence may lead to decreased signal integrity due to the reflections, quality loss, or noise and/or a reduced data rate of a data interchange between the connected components.

When driver 102 drives data to terminal 101 via switch 103 in a closed state, and signal line 104, the data rate which can be reached on signal line 104 can be limited by reflections caused by capacitive loadings on signal line 104, such as a capacitive loading caused by the driver 102. When switch 103 is in an open state, the capacitive loading of driver 102 is disconnected from signal line 104 connecting terminal 101, so that the capacitive loading of driver 102 may not cause reflections on signal line 104, so that the data rate may not be limited by such reflections.

Furthermore, the prevention of reflections on signal line 104 inhibits a generation of noise, thereby allowing a better signal integrity (i.e., transmission quality) on signal line 104.

Switch 103 (switching means) may be based on a transistor or may be a mechanical switch (mechanical switching means) (e.g., a circuit breaker, a mercury switch, a reed switch, a toggle switch, a push-button switch, a wafer switch, a micro switch, or the like).

Thus, according to a further embodiment, switch 103 need not be based on a transistor or a circuit comprising transistors. Further, switch 103 may be operable to be repeatedly opened and closed. Switch 103 may, thus, be toggled (i.e., activated/deactivated or opened/closed repeatedly).

Switch 103 may physically disrupt a connection between driver 102 and terminal 101, but could also be a switching device which causes a high resistance to be connected to line 104 between terminal 101 and driver 102 and thereby inhibit signal traffic (i.e., data transfer) on line 104.

In a further embodiment, switch 103 may be a micro-electromechanical system (MEMS) switch with low impedance. In this context, low impedance means impedance which is significantly lower than the impedance of, for example, a transistor or a transistor-based switching circuit.

According to a further embodiment shown in FIG. 2, an integrated circuit 200 comprises a further driver 105 which is connected to a signal line 204. As seen, further driver 105 is connected in parallel with switch 103 and driver 102. Switch 103 may disconnect driver 102 from terminal 101. However, due to the parallel arrangement of further driver 105 and switch 103, further driver 105 remains connected to signal line 204 despite the opening of switch 103. Further, driver 105 may be adapted to receive signals/data from terminal 101 via signal line 204 and to drive the data to further circuitry of integrated circuit 200. Such further circuitry may, for example, be storage cells of the integrated circuit. Thus, further driver 105 may also be referred to as “read driver”; since when seen from the side of terminal 101, data is read in the direction towards the further circuitry. Similarly, as for driver 102, when seen from the side of terminal 101/an external controller, further driver 105 may also be referred to as “write driver”, for example, driving data to be written into the further circuitry of integrated circuit 200.

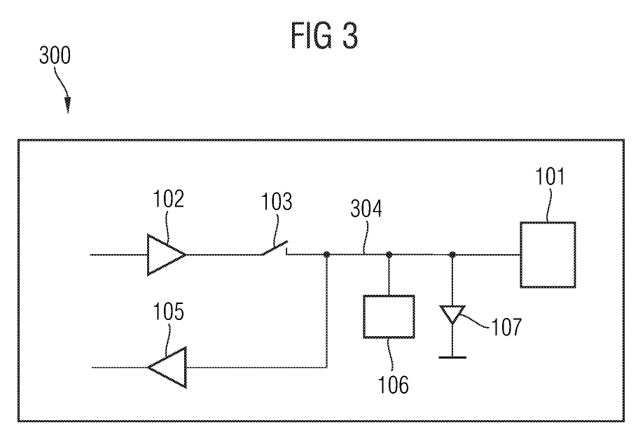

In a further embodiment shown in FIG. 3, a line terminator 106 and/or an electrostatic discharge section 107 may be connected to a signal line 304. Line terminator 106 may decrease reflections on signal line 304. Electrostatic discharge section 107 may protect signal line 304 from unwanted electrostatic discharge and may prevent a decrease of signal integrity and noise on signal line 304. Thus, load reflections on signal line 304 may be terminated and digital high- and low-state or analog signal reflections, as well as noise may be clamped (i.e., canceled).

However, in an arrangement without switch 103, reflections on line 304 and at any connected component may occur despite line terminator 106 and electronic discharge section 107. By changing the capacitive load on signal line 304, line terminator 106 may no longer be able to cancel all reflections on line 304. However, switch 103 allows the disconnection of driver 102 from line 304, whereby the adjustment of terminator 106 and electronic discharge section 107 is not disturbed by the capacitive load of driver 102.

As in the embodiment of FIG. 1, it is possible to control switch 103 to only close if data are driven by driver 102. Thus, also in the embodiment of FIG. 3, a higher data rate and a better signal integrity may be achieved due to fewer reflections on signal line 304.

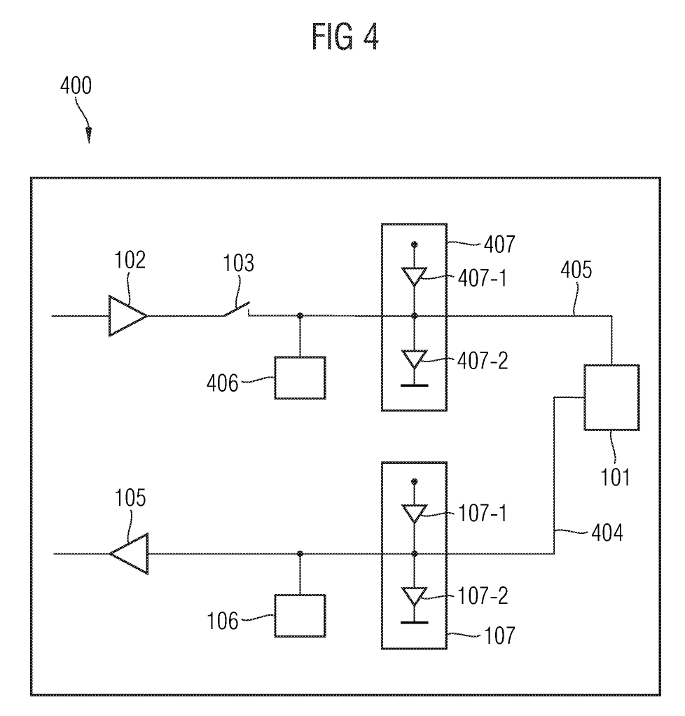

FIG. 4 shows a further embodiment, according to which an integrated circuit 400 comprises terminal 101 with two signal lines 404, 405 connected thereto. Driver 102, a line terminator 406 and an electronic discharge section 407 comprising electronic discharge devices 407-1, 407-2 are connected to signal line 405. Switch 103 may disconnect driver 102 from signal line 405 if driver 102 does not drive data to terminal 101 via signal line 405. Further driver 105, terminator 106 and electronic discharge section 107 comprising electronic discharge devices 107-1, 107-2 are connected to signal line 404. In this embodiment, all line terminators and electronic discharge sections are adjusted to cancel reflections, respectively, on the respective lines. These adjustments are not disturbed by connecting/disconnecting elements, or by changing loads on these lines, so that reflections may be suppressed.

FIG. 5 shows a further embodiment. In this embodiment, an integrated circuit 500 comprises a control circuit 501 adapted to control switch 103. Control circuit 501 may control switch 103 to connect driver 102 to terminal 101 via signal line 504 only if data are provided from driver 102 to terminal 101 via signal line 504. In this case, driver 102 may drive data to terminal 101 via signal line 504 and switch 103. If driver 102 may not provide data to terminal 101 via signal line 504, for example, in case further driver 105 may drive data from signal line 504 to a further circuitry of integrated circuit 500, control circuit 501 controls switch 103 to disconnect driver 102 from signal line 504. In that way, control circuit 501 controls the capacitive loading of driver 102 to be connected/disconnected to/from signal line 504 via switch 103. Electronic discharge section 107 comprises two electronic discharge devices 107-1, 107-2. Of course, in the embodiment of FIG. 5, it is also possible to provide two separate signal lines similar as in the embodiment of FIG. 4.

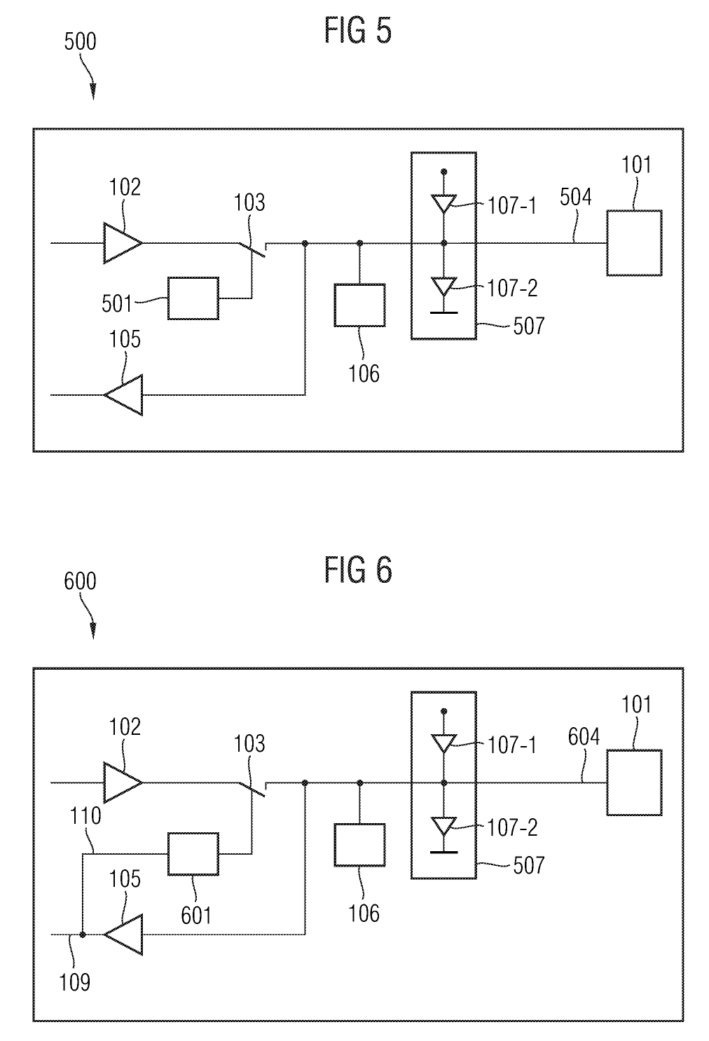

In a further embodiment as illustrated in FIG. 6, control circuit 601 is connected to an internal read line 109 via a control line 110. Internal read line 109 may be connected to an output of further driver 105 so that internal read line 109 may conduct signals or data, respectively, driven by further driver 105 to further internal circuitry of integrated circuit 600. Further, driver 105 drives data which may be input into integrated circuit 600 via terminal 101, for example, from an external device, and data driven by further driver 105 is provided (i.e., driven) to control circuit 601 via control line 110. Thus, control circuit 601 may be provided with data input from an external device into integrated circuit 600. The external device may be a controller of integrated circuit 600 and at least a part of the signal input from the controller into integrated circuit 600 may be interpreted or processed by control circuit 601 in order to generate a control signal for controlling switch 103 to connect or disconnect.

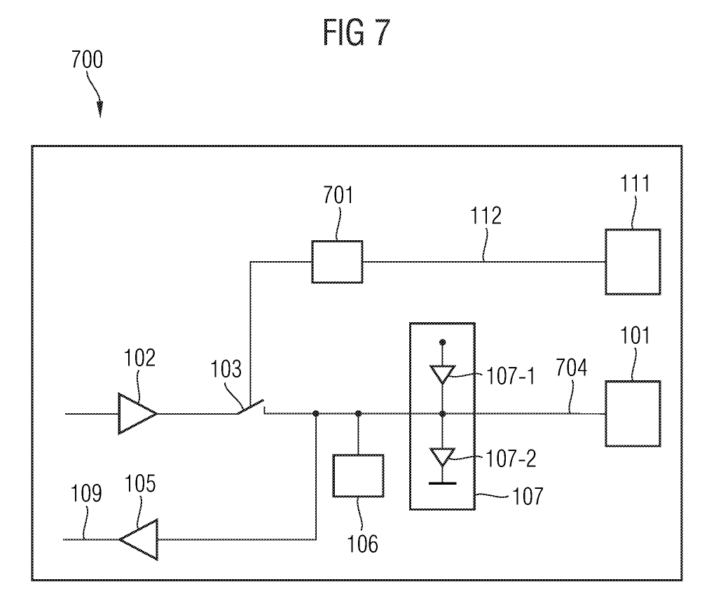

FIG. 7 shows a further embodiment, according to which the integrated circuit 700 may comprise: a signal line 704 and a further terminal 111 connected to control circuit 701 via a further terminal line 112. Further terminal 111 may, for example, be a connection pin or a connection pad, a jack for a plug, or any other means capable of engaging an electrical connection. Since further terminal 111 may be directly connected to an external device, the latter may provide integrated circuit 701 directly with information for controlling switch 103 to open or close, respectively.

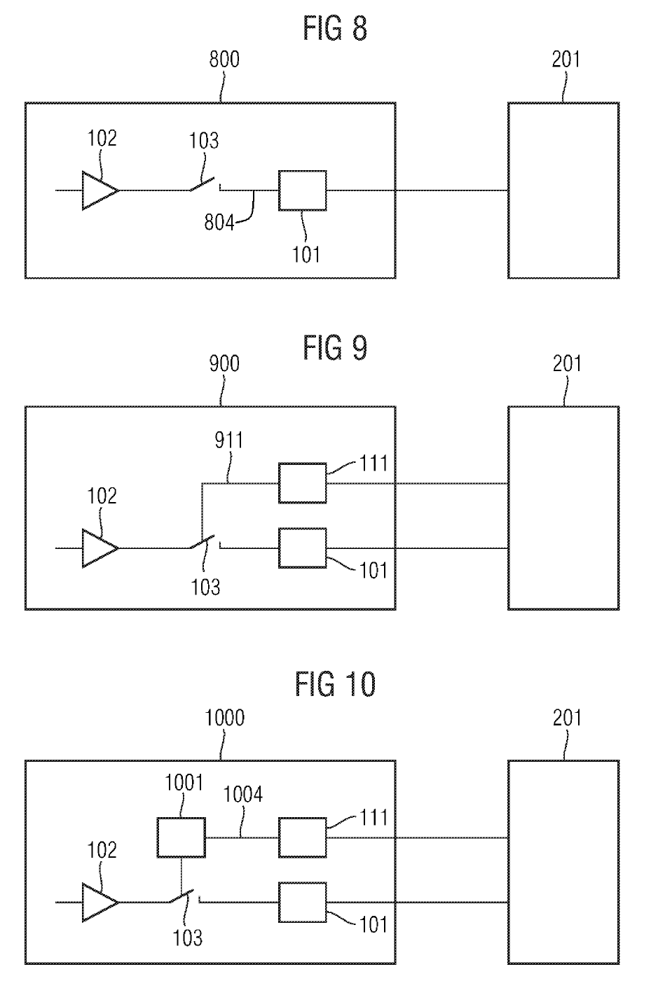

FIG. 8 shows a system according to an embodiment comprising a memory device 800 with terminal 101, driver 102, switch 103, signal line 804 as well as a memory controller 201. As stated above, switch 103 is adapted to connect/disconnect driver 102 to/from terminal 101. Memory controller 201 may be a controlling device for controlling memory device 800 by control signals, data commands, data instructions, analog or digital electrical levels or the like and may serve for controlling signals or data, respectively, to be written into memory device 800 or to be read from memory device 800. Memory device 800 and memory controller 201 are interconnected via terminal 101. Driver 102 may be a driver for driving data from memory device 800 to memory controller 201 via terminal 101 in case switch 103 is closed. In that case, terminal 101 is adapted to output data from memory device 800 into memory controller 201 (i.e., to input data from memory device 800 into memory controller 201).

FIG. 9 shows another embodiment, according to which a memory device 900 comprises further terminal 111 connected to switch 103 via further switch control line 911. In this case, external memory controller 201 may be adapted to provide a control signal based on which switch 103 is controllable.

FIG. 10 shows another embodiment, according to which a memory device 1000 comprises a terminal 111 and a control circuit 1001 interconnected via line 1004. In this embodiment, terminal 111 may provide a control signal of memory controller 201 to control switch 103 to open and close, respectively.

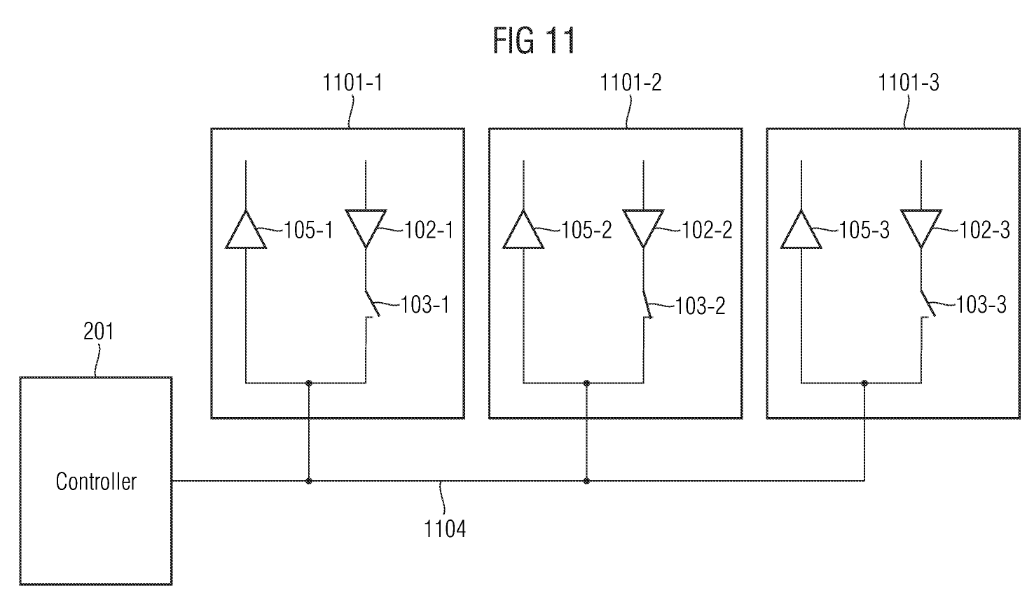

According to another embodiment shown in FIG. 11, a plurality of memory devices 1101-1, 1101-2, 1101-3 are connected to a memory controller 201 via a signal line 1104. Each memory device 1101-1, 1101-2, 1101-3 comprises a driver 102-1, 102-2, 102-3, a switch 103-1, 103-2, 103-3, and a further driver 105-1, 105-2, 105-3. Switches 103-1, 103-2, 103-3 are respectively adapted to connect/disconnect drivers 102-1, 102-2, 102-3 to/from signal line 1104-1. Switches 103-1, 103-2, 103-3 may respectively be adapted to open/close based on signal traffic on signal line 1104 based on an instruction or control signal provided by a further circuit or provided by the controller 201.

However, the respective switch 103-1, 103-2, 103-3 of a specific memory device 1101-1, 1101-2, 1101-3 would preferably close and thereby establish a connection between the respective driver 102-1, 102-2, 102-3 to signal line, for example, only if the respective driver 102-1, 102-2, 102-3 may drive data to controller 201 via signal line 1104. In case the respective driver 102-1, 102-2, 102-3 of the corresponding memory device 1101-1, 1101-2, 1101-3 may not drive data to controller 201, the respective switch 103-1, 103-2, 103-3 may disconnect driver 102-1, 102-2, 102-3 from controller 201, i.e., from signal line 1104. In other words, switches 102-1, 102-2, 102-3 may be operated independently from each other.

Memory device 1101-2 may send data to controller 201 via switch 103-2 and signal line 1104. Therefore, switch 103-2 is in a closed position in order to allow a connection to be established between driver 102-2 and signal line 1104. The other two memory devices 1101-1, 1101-3 may not send data to controller 201, i.e., the respective drivers 102-1, 102-3 may not drive data to controller 201 via signal line 1104. Therefore, the respective switch 103-1, 103-3 is open.

Opening these switches results in the capacitive loadings of drivers 102-1, 102-3 to not be connected to signal line 1104 and therefore the capacitive loadings of disconnected drivers 102-1, 102-3 do not cause signal reflections on signal line 1104. In case at least one of further drivers 105-1, 105-2, 105-3 is operated to drive data from controller 201 to further circuitries of the respective memory device 1101-1, 1101-2, 1101-3, only the signal reflections caused by driver 102-2 which is connected to signal line 1104 via switch 103-2 may occur on signal line 1104, so that fewer reflections occur on signal line 1104 than in case each driver 102-1, 102-2, 102-3 is connected thereto. In other words, a means for selectively reducing capacitive loading on the signal line reduces the number of signal reflections on the signal line.

The embodiment according to FIG. 11 makes clear that in a bus system where controller 201 is interconnected with a large number of memory devices 1101-1, 1101-2, 1101-3, . . . via bus signal line the reflections of all drivers 102-1, 102-2, 102-3, . . . can be very high in case all or at least some drivers 102-1, 102-2, 102-3, . . . are (or at least one driver is) connected to the bus signal line. By disconnecting a driver 102-1, 102-2, 102-3, . . . as often as possible from signal line 1104 which does not drive data, the load of these drivers 102-1, 102-3 causes fewer reflections on signal line 1104, resulting in a higher data rate and a better signal integrity on signal line 1104 (i.e., of the whole system). Notably, these improvements can be realized whenever switches 103 are open. Accordingly, even when switches 103 are not consistently opened when the signal line does not drive data, some degree of improvement exists whenever they are.

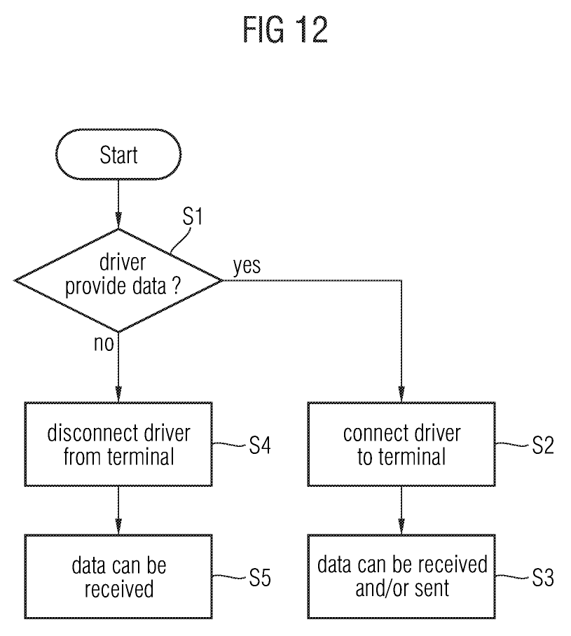

According to a further embodiment shown in FIG. 12, a method of operating an integrated circuit (e.g., memory device) is provided. In a step S1 it is checked if a driver of the memory device currently provides data to be transmitted to an external controller. If yes, in a step S2, a terminal of the memory device for inputting and/or outputting data into/from the memory device connects the driver to the terminal. Then, in a step S3, data can be received by the memory device and data can also be sent.

If the driver does not provide data, in a step S4, the driver is disconnected from the terminal. Then, in a step S5, data can be received by the memory device.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. An integrated circuit, comprising:
a terminal configured to output data;
a driver configured to provide the data to the terminal;
a signal line connecting the driver to the terminal; and
a switch in the signal line configured to connect/disconnect the driver to/from the terminal.

2. The integrated circuit according to claim 1, wherein the integrated circuit is a memory device and the driver or the terminal is configured to provide the data via the signal line to a controller operable to control the memory device.

3. The integrated circuit according to claim 1, wherein the switch is configured to connect the driver and the terminal, whenever the driver is providing data to the terminal.

4. The integrated circuit according to claim 1, wherein the switch is a mechanical switch.

5. The integrated circuit according to claim 1, wherein the switch is not transistor based.

6. The integrated circuit according to claim 1, wherein the switch is operable to be repeatedly opened and closed.

7. The integrated circuit according to claim 1, wherein the switch is a low impedance micro electromechanical system (MEMS) switch.

8. The integrated circuit according to claim 1, further comprising:
a further driver connected to the signal line in parallel with the switch and the driver.

9. The integrated circuit according to claim 8, wherein the further driver is configured to receive data from a controller via the terminal and the signal line.

10. The integrated circuit according to claim 9, further comprising:
a line terminator; and
an electrostatic discharge device, the line terminator and electrostatic discharge device being connected to the signal line.

11. The integrated circuit according to claim 8, wherein:
the driver is configured to drive data from the integrated circuit to an external controller; and
the further driver is configured to drive data from the external controller to further circuitry connected to an output of the further driver.

12. The integrated circuit according to claim 1, further comprising:
a control circuit configured to control the switch.

13. The integrated circuit according to claim 12, wherein the control circuit is configured to control the switch to connect the driver to the terminal only in the event that the driver is providing data.

14. An integrated circuit, comprising:
a data terminal;
at least one driver configured to provide data to the data terminal;
a signal line connecting the driver to the terminal; and
means for selectively reducing capacitive loading on the signal line.

15. A memory system, comprising:
a memory controller; and
a memory device, comprising:
a terminal configured to input/output data from/to the memory controller;
a driver configured to provide the data to the terminal; and
a switch configured to connect/disconnect the driver to/from the terminal.

16. The memory system according to claim 15, wherein the memory controller is configured to provide a control signal to control at least one of the memory device and the switch.

17. The memory system according to claim 16, wherein the memory device further comprises:
a further terminal, wherein the control signal is received by the memory device via the terminal or the further terminal.

18. The memory system according to claim 17, wherein the memory device further comprises:
a control circuit configured to receive the control signal and further configured to connect/disconnect the switch depending on the control signal.

19. The memory system according to claim 15, wherein the switch is controlled to connect the driver to the terminal only in the event that the data is provided by the driver.

20. A method of executing an operation via an integrated circuit including at least one signal line with a plurality of components connected thereto, the method comprising:
identifying at least one component that is not required to perform the operation;
selectively disconnecting at least one of the identified components from the signal line; and
executing the operation.

21. The method of claim 20, wherein the signal line has a first capacitive load associated at least in part with the components connected thereto.

22. The method of claim 21, wherein the disconnection of the one or more identified components results in a second capacitive load on the signal line different from the first capacitive load.

23. The method according to claim 20, further comprising:
providing a control signal to selectively control the connecting/disconnecting of the components from the signal line.

24. The method according to claim 23, wherein the control signal is provided by an external controller and/or by a control circuit of the integrated circuit.

25. An integrated circuit, comprising:
a data terminal;
a signal line connected to the data terminal; and
at least one driver selectively connected to the signal line; wherein the capacitive loading on the signal line is changed by the connection of the at least one driver thereto.

26. The integrated circuit according to claim 25, further comprising: a mechanical switch to selectively connect the driver to the signal line.
